(19) United States
(12) Patent Application Publication
(10) Pub. No.: US 2009/0058430 A1
(43) Pub. Date: Mar. 5, 2009

(54) Systems and Methods for Sensing Positions of Components

(75) Inventor: Haihong Zhu, Atlanta, GA (US)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: SENTRINSIC, Atlanta, GA (US)

(21) Appl. No.: 12/205,133

(22) Filed: Sep. 5, 2008

Related U.S. Application Data
(60) Provisional application No. 60/969,953, filed on Sep. 5, 2007.
(60) Provisional application No. 60/980,183, filed on Oct. 16, 2007.
(60) Provisional application No. 61/042,770, filed on Apr. 7, 2008.

(51) Int. Cl. G01R 27/08

(52) U.S. Cl. 324/691

(57) ABSTRACT

Systems and methods for sensing positions of components are provided. In this regard, a representative method includes: capacitively coupling the component to a resistive member without electrically connecting the component and the resistive member; moving the component relative to the resistive member while the component is capacitively coupled thereto; and measuring relative electrical impedance with respect to ends of the resistive member such that a position of the component is determined.

### CROSS REFERENCE TO RELATED APPLICATIONS

This application is a utility patent application that claims the benefit of and priority to the following U.S. Provisional Patent Applications: 60/969,953, filed Sep. 5, 2007, entitled “Capacitively Grounded Resistive Divider Sensing Method and Apparatus”; 60/980,183, filed Oct. 16, 2007, entitled “Capacitively Grounded Resistive Divider Sensing Method and Apparatus Extended”; and 61/042,770, filed Apr. 7, 2008, entitled “New and Extended Position Sensing Systems and Their Application to Fluid Power Cylinders”, each of which is incorporated herein by reference in its entirety.

### BACKGROUND

1. Technical Field

The disclosure generally relates to position sensing.

2. Description of the Related Art

Displacement sensors can be widely used in a number of industrial applications. Conventional displacement sensors have a variety of structures and working principles. Generally speaking, there are four major types of displacement sensing devices with four working principles, respectively. These include resistive displacement sensing (also known as potentiometer), inductive displacement sensing (e.g., LVDT, eddy current sensor, etc.), capacitive displacement sensing and optical displacement sensing (e.g., optical encoder). Other displacement sensing devices such as Hall Effect displacement sensors and magneto-restrictive sensors also are known.

### SUMMARY

Systems and methods for sensing positions of components are provided. In this regard, an exemplary embodiment of a method for sensing position of component comprising: capacitively coupling the component to a resistive member without electrically connecting the component and the resistive member; moving the component relative to the resistive member while the component is capacitively coupled thereto; and measuring relative electrical impedance with respect to ends of the resistive member such that a position of the component is determined.

An exemplary embodiment of a system with position sensing comprises: an electrically resistive member having a first end and a second end, the first end being operative to receive a first alternating signal; a component capacitively coupled to the resistive member, the component being movable with respect to the resistive member such that a position of capacitive coupling is movable within a range of positions located between the first end and the second; and a signal processor operative to determine a current position of the component relative to the resistive member based, at least in part, on a measure of relative impedance of the resistive member between the first end and a current position of capacitive coupling, and the current position of capacitive coupling and the second end.

Other systems, methods, features and/or advantages of this disclosure will be or may become apparent to one with skill in the art upon examination of the following drawings and detailed description. It is intended that all such additional systems, methods, features and/or advantages be included within this description and be within the scope of the present disclosure.

### BRIEF DESCRIPTION OF THE DRAWINGS

Many aspects of the disclosure can be better understood with reference to the following drawings. The components in the drawings are not necessarily to scale. Moreover, in the drawings, like reference numerals designate corresponding parts throughout the several views.

FIG. 1 is a schematic diagram depicting an exemplary embodiment of a system with position sensing.

FIG. 2 is flowchart depicting an exemplary embodiment of a method for sensing position.

FIGS. 3-7 are schematic diagrams depicting other exemplary embodiments of systems with position sensing.

### DETAILED DESCRIPTION

Systems and methods for sensing positions of components are provided, several exemplary embodiments of which will be described in detail. In some embodiments, capacitive coupling between two components that move relative to each other is used to alter electrical characteristics of the system. Measuring of the altered electrical characteristics is then correlated to determine position. In some embodiments, impedance is measured (e.g., relative impedance of two alternating electrical signals applied to one or more of the components) to determine the current position of at least one of the components.

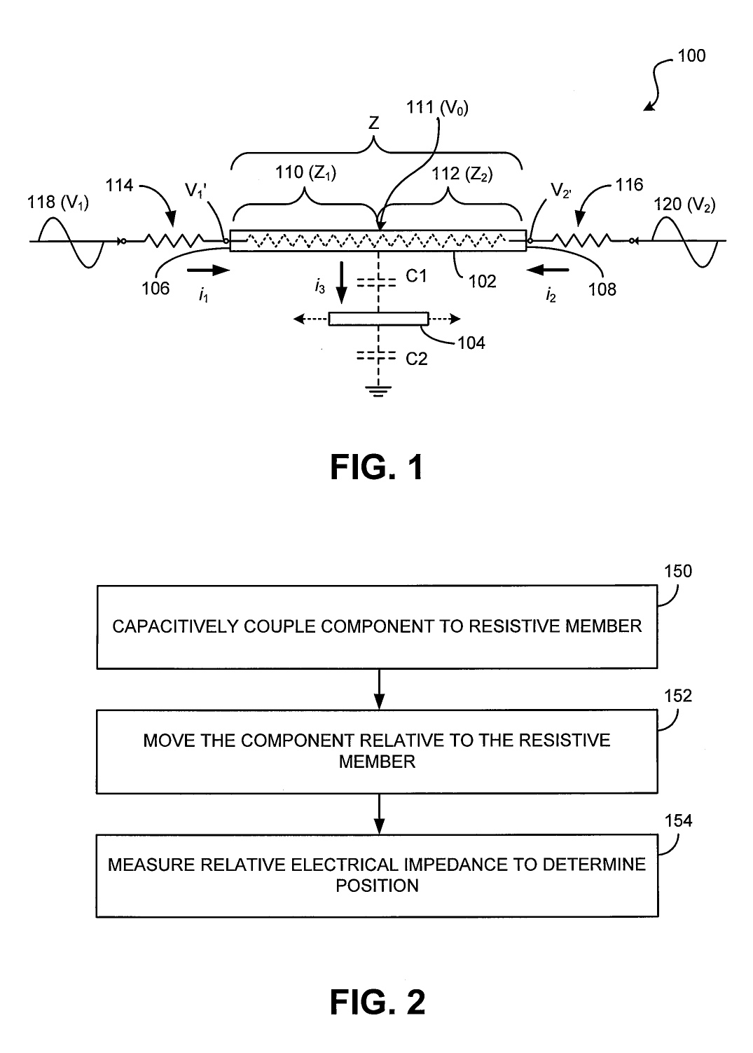

In this regard, reference is made to the schematic diagram of FIG. 1, which depicts an exemplary embodiment of a system with position sensing. As shown in FIG. 1, system 100 includes a resistive member 102 and a component 104 (also referred to as an “index coupler”) that moves relative to resistive member 102. In this embodiment, component 104 is oriented parallel to and moves linearly along a path oriented parallel to a surface of the resistive member. Note that component 104 and resistive member 102 are capacitively coupled to each other and are not electrically connected to each other.

Resistive member 102 exhibits ends 106, 108, with a portion 110 of the resistive member being defined between end 106 and a location 111 along the resistive member at which component 104 is capacitively coupled to the resistive member. Similarly, a portion 112 of the resistive member is defined between end 108 and the location of capacitive coupling. Notably, the location of capacitive coupling changes as the component moves relative to the resistive member.

System 100 additionally includes resistive elements 114, 116, each of which is electrically connected to a corresponding one of the ends of the resistive member. Specifically, resistive element 114 is connected to end 106 and resistive element 116 is connected to end 108.

In operation, alternating electrical signals 118, 120 (e.g., alternating (AC) voltage signals) are applied across resistive member 102 through resistive elements 114, 116, respectively. Although depicted as sinusoidal waveforms in FIG. 1, other types of alternating waveforms can be used in other embodiments, such as square waveforms. Additionally, component 104 is capacitively coupled to ground in FIG. 1 (by C2). In other embodiments, ground coupling could be provided in other configurations, such as by using a conductor to conductively couple the component to ground.

As component 104 moves relative to resistive member 102, the impedances associated with portion 110 (i.e., Z₁) and portion 112 (i.e., Z₂) change. One or both of these impedances and/or the impedance ratio (Z₁/Z₂) can be measured through the measuring of V₁′ and V₂′ and/or through the measuring of the currents i₁ and i₂. Besides these measurements, there are other methods that can derive the impedances and/or the impedance ratio.

It should be noted that with only one end being excited and the other end linked to ground or high impedance, there are multiple methods that can measure the impedance Z₁ (and/or Z₂) or the impedance ratio (Z₁/Z₂). By way of example, current i can be measured in relation to the excitation voltage and calculated by Z=V/i. However, direct measure of Z₁ and/or Z₂ involves the capacitance C1 and/or C2, which becomes an uncertain problem since C1 and/or C2 are prone to be affected by interference, temperature, etc.

With respect to dual-end excitation (such as shown in the embodiment of FIG. 1), various methods for determining impedance are known. However, these methods do not use resistive elements at both ends of the resistive member and/or determine the impedance ratio (Z₁/Z₂) by measuring the currents i₁ and i₂. Notably, one such known method directly applies the excitations at both ends, actively measures the voltage on the index coupler, and tries to set V₀ to zero (through adjusting V₁ and V₂). In practice, measuring of V₀ requires either a conductive wire (i.e., tethered to the index coupler, which tends to be a major failure point after excessive movements/cycles) or a conductive plate that is capacitively coupled to the index coupler from the opposite side of the resistive member. Unfortunately, interference (e.g., a nonzero voltage) at the index coupler or the conductive plate can cause the accuracy of the measurement of V₀ to be significantly affected.

In contrast, system 100 uses a non-tethered index coupler that is substantially immune to interference because V₀ is cancelled. Additionally, measurements are taken at the ends of the resistive member (which can be stationary) and no measurement is needed on the movable index coupler. It should be noted that a resistive member (in reality) also includes capacitance and inductance even though these characteristics can be rather small. Furthermore, the resistive member in practice may also exhibit a capacitive effect to ground. To provide a more accurate description of the resistive member, the impedance symbol Z instead of resistance symbol R is used in this disclosure.

The following is a discussion of methods for determining impedances and/or impedance ratio. Notably, based on electrical rules, following equation set can be easily established:

$$\{ \begin{matrix}{i}_{1} = ( {V}_{1} - {V}_{1}^{′} ) / {R}_{1} = ( {V}_{1}^{′} - {V}_{0} ) / {Z}_{1} \\ {i}_{2} = ( {V}_{2} - {V}_{2}^{′} ) / {R}_{2} = ( {V}_{2}^{′} - {V}_{0} ) / {Z}_{2} \\ {i}_{3} = {i}_{1} + {i}_{2}\end{matrix} \qquad ( 1 )$$

Based on equation set (1), four solutions to measure or calculate the impedances Z₁, Z₂ or impedance ratio (Z₁/Z₂) are presented. The impedances or impedance ratio corresponds to the position of the index coupler relative to the resistive member.

In this example (solution 1), set R₁=R₂=R, let V₁ and V₂ be of the same polarity, and measure V₁′ and V₂′. Then, adjust the amplitudes of V₁ and V₂, until V₁′=V₂′.

From equation set (1),

$$\{ \begin{matrix}{i}_{1} = ( {V}_{1} - {V}_{1}^{′} ) / R = ( {V}_{1}^{′} - {V}_{0} ) / {Z}_{1} \\ {i}_{2} = ( {V}_{2} - {V}_{2}^{′} ) / R = ( {V}_{2}^{′} - {V}_{0} ) / {Z}_{2}\end{matrix} \\ ⇒ {Z}_{2} \text{/} {Z}_{1} = ( {V}_{1} - {V}_{1}^{′} ) / ( {V}_{2} - {V}_{2}^{′} )$$

In above equation, V₀ is cancelled out. Thus, if the index coupler is affected by noise (e.g., a constant DC voltage is linked to the index coupler), the result is not affected. Therefore, this solution is highly immune to the interference and uncertainty of C1 and C2. Notably, the adjustments of V₁ and V₂ can be performed by either analog components (e.g. operational amplifiers) or a micro-processor through digital-to-analog conversion, for example.

In this example (solution 2), set R₁=R₂=R, let V₁ and V₂ be of inverse polarity, and measure V₁′ and V₂′. Then, adjust the amplitudes of V₁ and V₂ until

(V₁−V₁)=−(V₂−V₂′).

This results in the following:

(V₁−V₁′)=−(V₂−V₂′)

[symbol]

(V₁−V₁′)/R=−(V₂−V₂′)/R

[symbol]

i₁=−i₂

[symbol]

i₃=i₁+i₂=0

[symbol]

V₀=ground potential=0

Using V₀ in the following equation set

$$\{ \begin{matrix}{i}_{1} = ( {V}_{1} - {V}_{1}^{′} ) / R = ( {V}_{1}^{′} - {V}_{0} ) / {Z}_{1} \\ {i}_{2} = ( {V}_{2} - {V}_{2}^{′} ) / R = ( {V}_{2}^{′} - {V}_{0} ) / {Z}_{2}\end{matrix}$$

the result is as follows:

Z₂/Z₁=−V₂′/V₁′.

In solution 2, if any voltage or noise influences the index coupler, V₀ is no long zero (but equal to the interference potential). Therefore, the index coupler is not immune to the interference as in solution 1.

In this example (solution 3), use the same excitation at both ends of the resistive member, (i.e., V₁=V₂=V) and measure V₁′ and V₂′. The impedances Z₁ and Z₂ can be directly calculated through following equation set:

$$\{ \begin{matrix}{i}_{1} = ( V - {V}_{1}^{′} ) / {R}_{1} = ( {V}_{1}^{′} - {V}_{0} ) / {Z}_{1} \\ {i}_{2} = ( V - {V}_{2}^{′} ) / {R}_{2} = ( {V}_{2}^{′} - {V}_{0} ) / {Z}_{2} \\ {Z}_{1} + {Z}_{2} = Z\end{matrix} \\ ⇒ \\ \{ \begin{matrix}\frac{( V - {V}_{1}^{′} ) \cdot {Z}_{1}}{{R}_{1}} - \frac{( V - {V}_{2}^{′} ) \cdot {Z}_{2}}{{R}_{2}} = {V}_{1}^{′} - {V}_{2}^{′} \\ {Z}_{1} + {Z}_{2} = Z\end{matrix}$$

In the above equation set, Z, R₁, R₂, V₁′ and V₂′ are known. Therefore, Z₁ and Z₂ can be solved. Please note, in this solution, single excitation is applied and no adjustment is needed. Thus, the result is independent of V₀. Therefore, this solution also is substantially immune to interference. Accurate results depend on the accuracy of Z, R₁ and R₂, which can be experimentally measured and/or calibrated, e.g., calibrated at the first time of use of a system implementing this solution.

In this example (solution 4), current is directly measured (such as by using an integrated circuit). Once i₁,i₂ are measured, results from equation set (1) can be calculated. For simplicity, set R₁=R₂=0, and set V₁=V₂=V, resulting in

$$\{ \begin{matrix}{i}_{1} = ( V - {V}_{0} ) / {Z}_{1} \\ {i}_{2} = ( V - {V}_{0} ) / {Z}_{2}\end{matrix} \\ ⇒ {Z}_{1} \text{/} {Z}_{2} = {i}_{2} / {i}_{1}$$

In this solution, V₀ is also cancelled out. Therefore, the index coupler is substantially immune from interference.

Resistive members can be excited using various alternating current signals, e.g., sinusoidal waveform, square waveform or saw waveform. For ease of description, use of square waveform excitation and signal conditioning is discussed.

Waveform excitation and conditioning excites both ends of a resistive member and then the signals (either voltage or current depending on the embodiment) are measured. The impedances of the resistive member are then calculated and the position of the index coupler is derived according to the impedances and/or impedance ratio. In those embodiments in which the impedance directly relates to the position of the index coupler, calculations of the actual impedance values are not necessary. In other words, the position can be derived directly from the impedance ratio.

In some embodiments, adjustment of excitation voltages is involved. For instance, when the voltages are of the same polarity (e.g., solution 1), if V1′>V2′, the amplitude of V2 can be increased and/or the amplitude of V1 can be decreased. However, if V1′<V2′, the amplitude of V1 can be increased and/or the amplitude of V2 can be decreased. The aforementioned can be repeated until V1′=V2′. Thereafter, the calculations shown above with respect to solution 1 can be performed.

In some embodiments in which adjustment of excitation voltages is involved and the voltages are of inverse polarity (e.g., solution 2), if (V1−V1′)>−(V2−V2′), the amplitude of V1 can be decreased or the amplitude of V2 can be increased. If the derivative of V1<the derivative of V2, the amplitude of V1 can be decreased and the amplitude of V2 can be increased. However, if (V1−V1′)<−(V2−V2′), the amplitude of V1 can be increased or the amplitude of V2 can be decreased. If the derivative of V1>the derivative of V2, the amplitude of V1 can be increased and the amplitude of V2 can be decreased. The aforementioned can be repeated until (V1−V1′)=−(V2−V2′). Thereafter, the calculations shown above with respect to solution 2 can be performed.

Various devices can be used to perform the functions above, such as analog devices (e.g., operational amplifiers) or digital devices (e.g., microprocessors). In this regard, digital to analog converters can be used for adjusting excitation, for example, and analog to digital converters can be used for sensing V1′ and V2′, for example. Additionally, such as when using sinusoidal excitation, the voltage and/or current can be demodulated and processed. Further filtering and/or other digital processing may be applied depending upon the particular application. Final results can be output to external systems or users via various communication protocols and/or displays.

In this regard, FIG. 2 is a flowchart depicting an exemplary embodiment of a method for sensing position of an electrically conductive component. Specifically, the method may be construed as beginning at block 150, in which the component is capacitively coupled to a resistive member without electrically connecting the component and the resistive member. In block 152, the component is moved relative to the resistive member while the component is capacitively coupled to the resistive member. Then, as depicted in block 154, relative electrical impedance is measured with respect to ends of the resistive member such that a position of the component is determined.

The component is coupled (e.g., conductively, capacitively and/or inductively coupled) to an electrical source or sink. This provides a path for the electrical current(s) applied to propagate through the component. The direction of current flow is inconsequential, in that the current can either be from the source/sink, through the component and then to the end(s) of the resistive member, or from the end(s) of the resistive member, through the component and then to the source/sink. In some embodiments, the voltage of the source/sink can be zero (i.e., ground), alternating (e.g., sinusoidal) or constant (e.g., a DC source).

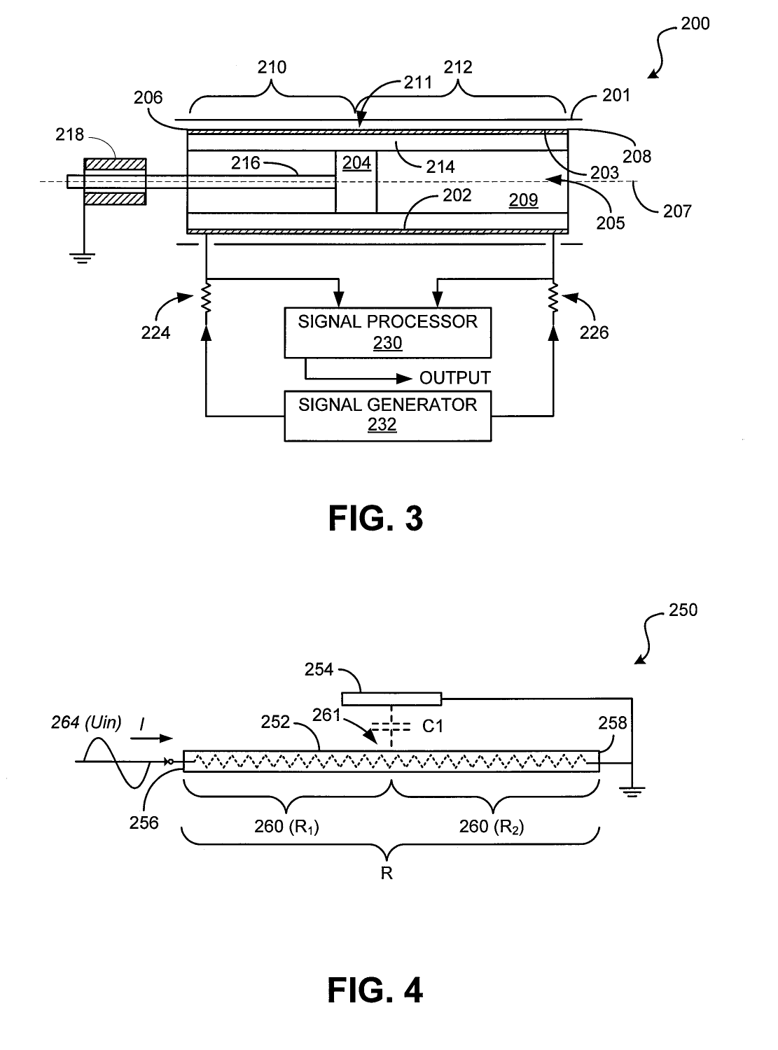

FIG. 3 is another exemplary embodiment of a system with position sensing that can be used to implement the functionality described above with respect to FIG. 2. As shown in FIG. 3, system 200 incorporates a housing 201 that includes an inner wall 203 for defining a cylindrical interior cavity 205. A resistive member 202 is positioned against the inner wall. In this embodiment, the resistive member is formed of resistive film, although various other forms and/or configurations can be used in other embodiments. A component 204 (also referred to as an “index coupler”) is configured as a piston that moves relative to resistive member 202. In this embodiment, the piston moves along a longitudinal axis 207 of the interior cavity 205. In this manner, operating fluid 209 can be influenced by the position of the piston. In some embodiments, the operating fluid can be hydraulic fluid.

Resistive member 202 exhibits ends 206, 208, with a portion 210 of the resistive member being defined between end 206 and a location 211 along the resistive member at which component 204 is capacitively coupled to the resistive member. Similarly, a portion 212 of the resistive member is defined between end 208 and the location of capacitive coupling. Notably, dielectric material 214 is positioned radially between the component and the resistive member to facilitate the capacitive coupling. In this embodiment, the radially outer diameter surface of the dielectric material contacts the radially inner diameter surface of the resistive member.

In the embodiment of FIG. 3, component 204 is more electrically conductive than resistive member 202. Additionally, an electrically conductive piston rod 216 is connected to the piston, with a support 218 being located outside of the interior cavity. Support 218 axially supports the piston rod and is electrically connected to ground. This configuration capacitively couples component 204 to ground.

System 200 additionally includes resistive elements 224, 226, each of which is electrically connected to a corresponding one of the ends of the resistive member. Specifically, resistive element 224 is connected to end 206 and resistive element 226 is connected to end 208. A signal generator 230 is used to apply alternating electrical signals to the resistive member and a signal processor 232 is used to determine a current position of component 204 relative to resistive member 202.

In operation, alternating electrical signals 228, 229 are applied by signal generator 230 across resistive member 202 through resistive elements 224, 226, respectively. Notably, in some embodiments, a single signal can be divided to provide the two alternating signals.

Signal processor 232 determines the system response to the signals including determining a current position of the component relative to the resistive member. This is accomplished, at least in part, based on a measure of relative impedance of portions 210 and 212 of the resistive member (see exemplary calculations above). Notably, the signal processor determines the current position of the component without using a signal originating from the component.

It should be noted that determination of the current position of the piston does not rely on the capacitances between the piston and the resistive member, and between the piston rod and support. Thus, capacitance variation does not change the accuracy of the measurements used for the determination.

Note also that that although the embodiment of FIG. 3 utilizes a separate signal generator and signal processor, various other configurations can be used in other embodiments. By way of example, other embodiments can incorporate a microprocessor that performs both signal generation and signal processing functions with or without additional components, e.g., analog-to-digital and/or digital-to-analog converters.

FIG. 4 is a schematic diagram depicting another exemplary embodiment of a system with position sensing. As in the previous embodiments, an alternating signal is used to facilitate a measurement of impedance; however, in contrast to those embodiments, a ground signal is used instead of a second alternating signal.

As shown in FIG. 4, system 250 includes a resistive member 252 and a component 254 (also referred to as an “index coupler”) that moves relative to resistive member 252. In this embodiment, component 254 is oriented parallel to and moves linearly along a path that is oriented parallel to a surface of the resistive member. Note that component 254 and resistive member 252 are capacitively coupled to each other and are not electrically connected to each other.

Resistive member 252 exhibits ends 256, 258, with a portion 260 of the resistive member being defined between end 256 and a location 261 along the resistive member at which component 254 is capacitively coupled to the resistive member. Similarly, a portion 262 of the resistive member is defined between end 258 and the location of capacitive coupling. Notably, the location of capacitive coupling changes as the component moves relative to the resistive member.

An alternating electrical signal 264 is applied to end 256 of the resistive member and an electrical ground signal is applied to end 258. Component 254 also is electrically connected to ground.

In operation, the impedance of the system can be found using the following relationship:

$$Z = R - \frac{{R}_{2}^{2} {C}_{1} j ω}{{R}_{2} {C}_{1} j ω + 1}$$

As mentioned, there are numerous methods to measure the impedance. The following example can be used to measure the current I at the point of excitation:

$$I - [ \frac{R + {RR}_{2} {C}_{1} ω + {R}_{1} {R}_{2}^{2} {C}_{1}^{2} {ω}^{2}}{{R}^{2} + {R}_{1}^{2} {R}_{2}^{2} {C}_{1}^{2} {ω}^{2}} - \frac{{R}_{1} {R}_{2} {C}_{1} ω}{{R}^{2} + {R}_{1}^{2} {R}_{2}^{2} {C}_{1}^{2} {ω}^{2}} j ] \cdot {U}_{in}$$

Here, ω is the frequency of the excitation voltage Uᵢₙ.
Therefore, when ω→∞,

$$I = \frac{1}{{R}_{1}} \cdot {U}_{in} .$$

As before, the resistive member is excited using an alternating signal. With respect to a square waveform, this can involve applying step excitation to end 256 and then measuring the signal. The excitation is then turned off, impedance of the system is calculated and the position of the index coupler is derived according to the impedance. Since the impedance directly relates to the position of the index coupler, the above calculation and derivation can be performed in one step, i.e., the impedance is not necessary to be calculated out. In other words, the position is derived directly from the measured signal. Post data analysis (e.g., filtering, other digital processing, etc.) may be applied depending on the particular application. Results can be output to a user using various communication protocols.

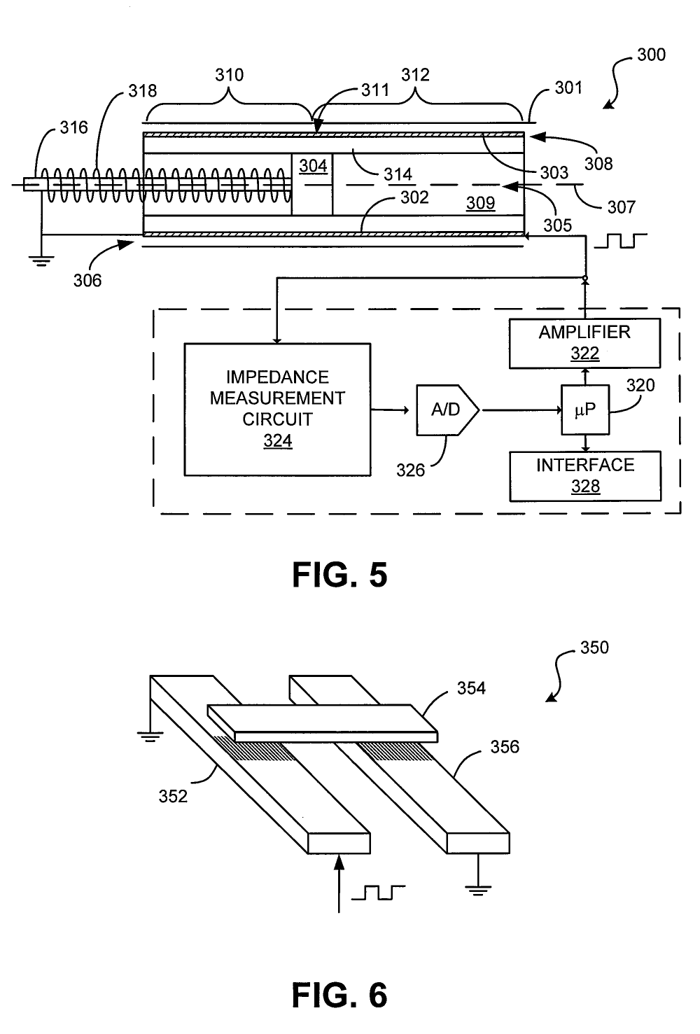

FIG. 5 is a schematic diagram depicting another exemplary embodiment of a system with position sensing. As shown in FIG. 5, system 300 incorporates a housing 301 that includes an inner wall 303 for defining a cylindrical interior cavity 305. A resistive member 302 is positioned against the inner wall. In this embodiment, the resistive member is formed of resistive film, although various other forms and/or configurations can be used in other embodiments. A component 304 (also referred to as an “index coupler”) is configured as a piston that moves relative to resistive member 302. In this embodiment, the piston moves along a longitudinal axis 307 of the interior cavity 305. In this manner, operating fluid 309 can be influenced by the position of the piston. In some embodiments, the operating fluid can be hydraulic fluid.

Resistive member 302 exhibits ends 306, 308, with a portion 310 of the resistive member being defined between end 306 and a location 311 along the resistive member at which component 304 is capacitively coupled to the resistive member. Similarly, a portion 312 of the resistive member is defined between end 308 and the location of capacitive coupling. Notably, dielectric material 314 is positioned radially between the component and the resistive member to facilitate the capacitive coupling. In this embodiment, the radially outer diameter surface of the dielectric material contacts the radially inner diameter surface of the resistive member.

In the embodiment of FIG. 5, a piston rod 316 is connected to the piston. The piston is electrically connected to ground via a grounding spring 318 through which piston rod 316 is inserted. This configuration capacitively couples component 304 to ground. Notably, since grounding of the piston is facilitated by the grounding spring, the piston rod need not be conducting. Note also that, in some embodiments, the grounding spring can be located on the opposite side of the piston form that shown in FIG. 5.

System 300 additionally includes a microprocessor 320 that generates a square waveform excitation in this embodiment. The excitation is amplified by amplifier 322 so that an amplified, alternating electrical signal is applied to the resistive member at end 308. The excitation is fed back to an impedance measurement circuit 324, which is an analog device in this embodiment. The output analog signal of circuit 324 is provided to an analog-to-digital converter 326, with the output of converter 326 being provided to microprocessor 320 for processing (such as described before) to determine a current position of component 304 relative to resistive member 302. Output from microprocessor is communicated via interface 328.

FIG. 6 is a schematic diagram depicting another exemplary embodiment of a system with position sensing. In contrast to the embodiments of FIGS. 3 and 5, however, this embodiment exhibits a non-cylindrical form factor.

As shown in FIG. 6, system 350 includes a resistive member 352 configured as a rail and a component (“index coupler”) configured as a bridge. Component 354 moves along and is supported by resistive member 352 and a conductive rail 356 that is connected to ground. Notably, in this embodiment, resistive member 352 also is connected to ground with a single excitation being provided to the resistive member. In other embodiments, dual-end excitation can be used.

With respect to the single excitation, excitation current passes through the resistive member, the capacitor formed between the index coupler and the resistive member, the index coupler, the capacitor formed between the index coupler and the conductive rail, the conductive rail, and then to ground. Therefore, in this embodiment, C1 (see discussion above) is the lump sum of the capacitance formed between the index coupler-resistive member and the capacitance of the index coupler-conductive rail. In some embodiments, such as those in which adequate support of the index coupler is provided by the resistive member, the conductive rail can be replaced by a less structural component, such as a conductive wire directly linking the index coupler ground.

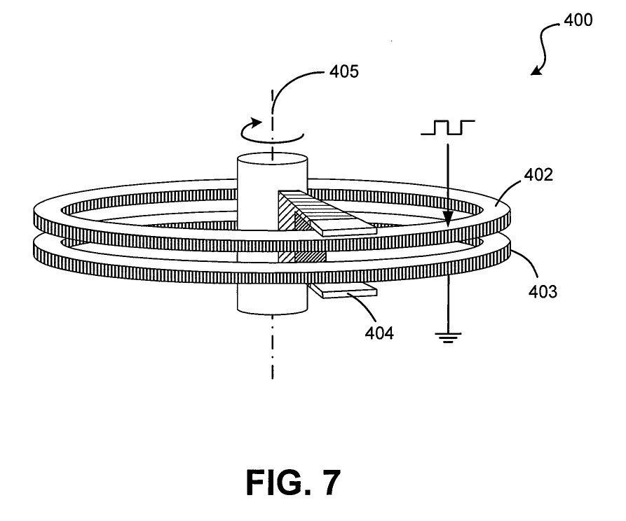

FIG. 7 is a schematic diagram depicting another exemplary embodiment of a system with position sensing. In contrast to the embodiments of FIGS. 3, 5 and 6 that exhibit linear motion of the corresponding index couplers, the index coupler of this embodiment exhibits a non-linear motion and can be useful in determining angular displacement.

As shown in FIG. 7, system 400 includes a circular resistive member 402, a circular (grounded) conductive member 403 and a component 404 (“index coupler”). Component 404 moves about the circumferences of the circular members 402, 403 and is capacitively coupled to each.

In operation, excitation current passes through the resistive member, the capacitor formed between the index coupler and the resistive member, the index coupler, the capacitor formed between the index coupler and the conductive member, the conductive member, and then to ground. Therefore, in this embodiment, C1 (see discussion above) is the lump sum of the capacitance formed between the index coupler-resistive member and the capacitance of the index coupler-conductive member. Notably, various other components associated with determining the current position of the index coupler have been omitted here as the principles have been described previously. Note also that dual-end excitation can be used in various configurations of resistive and conductive members. Additionally, although the resistive member and conductive member are concentric rings of similar inner and outer diameter in this embodiment, various other configurations can be used.

Various functionality, such as that described above in the flowcharts, can be implemented in hardware and/or software. In this regard, a computing device can be used to implement various functionality (such as that depicted in FIG. 2) and/or in association with a signal processor, for example.

In terms of hardware architecture, such a computing device can include a processor, memory, and one or more input and/or output (I/O) device interface(s) that are communicatively coupled via a local interface. The local interface can include, for example but not limited to, one or more buses and/or other wired or wireless connections. The local interface may have additional elements, which are omitted for simplicity, such as controllers, buffers (caches), drivers, repeaters, and receivers to enable communications. Further, the local interface may include address, control, and/or data connections to enable appropriate communications among the aforementioned components.

The processor may be a hardware device for executing software, particularly software stored in memory. The processor can be a custom made or commercially available processor, a central processing unit (CPU), an auxiliary processor among several processors associated with the computing device, a semiconductor based microprocessor (in the form of a microchip or chip set) or generally any device for executing software instructions.

The memory can include any one or combination of volatile memory elements (e.g., random access memory (RAM, such as DRAM, SRAM, SDRAM, VRAM, etc.)) and/or nonvolatile memory elements (e.g., ROM, hard drive, tape, CD-ROM, etc.). Moreover, the memory may incorporate electronic, magnetic, optical, and/or other types of storage media. Note that the memory can also have a distributed architecture, where various components are situated remotely from one another, but can be accessed by the processor.

The software in the memory may include one or more separate programs, each of which includes an ordered listing of executable instructions for implementing logical functions. A system component embodied as software may also be construed as a source program, executable program (object code), script, or any other entity comprising a set of instructions to be performed. When constructed as a source program, the program is translated via a compiler, assembler, interpreter, or the like, which may or may not be included within the memory.

The Input/Output devices that may be coupled to system I/O Interface(s) may include input devices, for example but not limited to, a keyboard, mouse, scanner, microphone, camera, proximity device, etc. Further, the Input/Output devices may also include output devices, for example but not limited to, a printer, display, etc. Finally, the Input/Output devices may further include devices that communicate both as inputs and outputs, for instance but not limited to, a modulator/demodulator (modem; for accessing another device, system, or network), a radio frequency (RF) or other transceiver, a telephonic interface, a bridge, a router, etc.

When the computing device is in operation, the processor can be configured to execute software stored within the memory, to communicate data to and from the memory, and to generally control operations of the computing device pursuant to the software. Software in memory, in whole or in part, is read by the processor, perhaps buffered within the processor, and then executed.

One should note that the flowcharts included herein show the architecture, functionality, and operation of a possible implementation of software. In this regard, each block can be interpreted to represent a module, segment, or portion of code, which comprises one or more executable instructions for implementing the specified logical function(s). It should also be noted that in some alternative implementations, the functions noted in the blocks may occur out of the order and/or not at all. For example, two blocks shown in succession may in fact be executed substantially concurrently or the blocks may sometimes be executed in the reverse order, depending upon the functionality involved.

One should note that any of the functionality described herein can be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” contains, stores, communicates, propagates and/or transports the program for use by or in connection with the instruction execution system, apparatus, or device. The computer readable medium can be, for example but not limited to, an electronic, magnetic, optical, electromagnetic, infrared, or semiconductor system, apparatus, or device. More specific examples (a nonexhaustive list) of a computer-readable medium include a portable computer diskette (magnetic), a random access memory (RAM) (electronic), a read-only memory (ROM) (electronic), an erasable programmable read-only memory (EPROM or Flash memory) (electronic), and a portable compact disc read-only memory (CDROM) (optical).

It should be emphasized that the above-described embodiments are merely possible examples of implementations set forth for a clear understanding of the principles of this disclosure. Many variations and modifications may be made to the above-described embodiments without departing substantially from the spirit and principles of the disclosure. All such modifications and variations are intended to be included herein within the scope of this disclosure and protected by the accompanying claims.

1. A method for sensing position of an electrically conductive component comprising:
capacitively coupling the component to a resistive member without electrically connecting the component and the resistive member;
moving the component relative to the resistive member while the component is capacitively coupled thereto; and
measuring relative electrical impedance with respect to ends of the resistive member such that a position of the component is determined.

2. The method of claim 1, wherein the position of the component is determined without using a direct electrical measurement of the component.

3. The method of claim 1, wherein the measuring comprises applying a first alternating electrical signal to a first of the ends of the resistive member.

4. The method of claim 3, wherein:
in applying the first alternating electrical signal, the first alternating electrical signal is applied across a first resistive element, the first resistive element being electrically connected to the first of the ends; and
the measuring further comprises measuring a first voltage drop across the first resistive element.

5. The method of claim 3, wherein the measuring further comprises applying a second alternating electrical signal to a second of the ends of the resistive member.

6. The method of claim 3, wherein the measuring further comprises applying an electrical ground signal to a second of the ends of the resistive member.

7. The method of claim 1, wherein moving the component comprises moving an operating fluid.

8. A system with position sensing comprising:
an electrically resistive member having a first end and a second end, the first end being operative to receive a first alternating signal;
a component capacitively coupled to the resistive member, the component being movable with respect to the resistive member such that a position of capacitive coupling is movable within a range of positions located between the first end and the second; and
a signal processor operative to determine a current position of the component relative to the resistive member based, at least in part, on a measure of relative impedance of the resistive member between the first end and a current position of capacitive coupling, and the current position of capacitive coupling and the second end.

9. The system of claim 8, wherein the signal processor is operative to determine the current position of the component without using a signal originating from the component.

10. The system of claim 8, further comprising:
a first resistive element electrically connected to the first end; and
a signal generator operative to apply a first alternating electrical signal to the first resistive element.

11. The system of claim 10, wherein the second end of the resistive member is electrically connected to ground.

12. The system of claim 10, further comprising second resistive element electrically connected to the second end, the second resistive element being operative to receive a second alternating electrical signal.

13. The system of claim 12, wherein the signal generator is operative to provide both the first alternating electrical signal and the second alternating electrical signal.

14. The system of claim 12, wherein the first alternating electrical signal and the second alternating electrical signal are sinusoidal.

15. The system of claim 8, wherein the resistive member is cylindrical defining a longitudinal axis.

16. The system of claim 15, wherein:
the system further comprises a housing defining an interior cavity;
the resistive member is positioned within the interior cavity; and
the component is a piston positioned within the resistive member and operative to move along the longitudinal axis.

17. The system of claim 16, further comprising an operating fluid located within the interior cavity and contacting the piston.

18. The system of claim 15, further comprising dielectric material positioned radially between the component and the resistive member.

19. The system of claim 15, further comprising:
an electrically conductive piston rod connected to the piston; and
a support located outside of the interior cavity and being operative to support the piston rod, the support being electrically connected to ground.

20. The system of claim 8, wherein the component is more electrically conductive relative to the resistive member.
